(19) United States
(12) Patent Application Publication
(10) Pub. No.: US 2024/0069226 A1
(43) Pub. Date: Feb. 29, 2024

(54) METHOD FOR AUTOMATICALLY PICKING UP SEISMIC VELOCITY BASED ON DEPTH LEARNING

(71) Applicant: China University of Mining and Technology (Beijing), Beijing (CN)

(72) Inventors: Suzhen SHI, Beijing (CN); Mingxuan LI, Beijing (CN)

(21) Appl. No.: 17/396,603

(22) Filed: Aug. 6, 2021

(30) Foreign Application Priority Data
Oct. 23, 2020 (CN) 2020111494320

(51) Int. Cl. G01V 1/28; G01V 1/30

(52) U.S. Cl. CPC G01V 1/282; G01V 1/303; G01V 2210/675; G01V 2210/677

(57) ABSTRACT

A method for automatically picking up seismic velocity based on depth learning is disclosed. The method includes obtaining a seismic data and labels, and inputting the seismic data and the labels into a pre-trained depth learning model to obtain a velocity pick-up result. A structure of the depth learning model includes a residual network composed of three residual blocks. And after the residual network, a long-short term memory network and a full connection layer are further added. Each of the residual blocks is composed of three convolutional layers. An activation function between each residual block and each convolutional layer of the residual block is a Relu function. An activation function between the long-short term memory network and the full connection layer is a Relu function. The method for automatically picking up seismic velocity based on depth learning provided by the disclosure effectively improves the efficiency of seismic velocity pick-up.

### CROSS REFERENCE TO RELATED APPLICATION

This patent application claims the benefit and priority of Chinese Patent Application No. 202011149432.0 filed on Oct. 23, 2020, the disclosure of which is incorporated by reference herein in its entirety as part of the present application.

### TECHNICAL FIELD

The disclosure relates to the technical field of seismic velocity pick-up, more specifically, to a method for automatically picking up seismic velocity based on depth learning.

### BACKGROUND ART

Establishing velocity model is an important step in seismic data processing. The quality of establishing velocity model have an important impact on the subsequent processing of seismic data, such as multiple suppression, time depth conversion, migration imaging and inversion.

To establish the velocity model, it is necessary to pick up the velocity on the velocity spectrum. This process usually requires professionals to pick up the velocity manually and takes a lot of time. When velocity spectrum is used to pick up the velocity, the accuracy of picking up velocity and the resolution of velocity spectrum are affected by many factors, such as offset distribution, superposition times, signal-to-noise ratio, velocity sampling density and near surface anomaly. Therefore, it needs experienced processing personnel to get high precision picking results. Because of the huge amount of 3D seismic data, it is time-consuming and inefficient to pick up the velocity spectrum only by manual method in seismic data processing.

Therefore, it is an urgent problem for those skilled in the art to improve the efficiency of seismic velocity pick-up.

### SUMMARY

In view of the above, the present disclosure provides a method for automatically picking up seismic velocity based on depth learning to improve the efficiency of seismic velocity pick-up.

In order to achieve the above purpose, technical solutions of the present disclosure are specifically described as follows.

The method for automatically picking up seismic velocity based on depth learning includes the following steps:
obtaining a seismic data and labels; and
inputting the seismic data and the labels into a pre-trained depth learning model to obtain a velocity pick-up result.

A structure of the depth learning model includes a residual network composed of three residual blocks, and after the residual network, a long-short term memory network and a full connection layer are further added.

Each of the residual blocks is composed of three convolutional layers. An activation function between each residual block and each convolutional layer of the residual block is a Relu function. And an activation function between the long-short term memory network and the full connection layer is a Relu function.

Preferably, a method for training the depth learning model includes:
constructing a training set data and labels;
constructing the depth learning model; and
inputting the training set data and the labels into the constructed depth learning model for training, and further training the depth learning model by using a migration learning.

Preferably, the step of constructing a training set data and labels includes:
establishing a horizontal layered velocity model;
performing a forward modeling on the horizontal layered velocity model based on a wave equation to obtain seismic records;
synthesizing a CMP gather based on the seismic records;
calculating a velocity spectrum based on the CMP gather;
dividing the velocity spectrum equally into m regions according to a time axis, displaying a region shape of energy information, and setting an energy value of other regions to 0 to obtain a processed velocity spectrum;
superimposing the processed velocity spectrum with the original velocity spectrum to obtain the training set data; and
extracting velocity values corresponding to energy maximum points in each region, and configuring the velocity values as the labels.

Preferably, the step of further training the depth learning model by using a migration learning includes:
extracting n velocity spectra from an actual seismic data, and obtaining labels by manually picking up velocities; and
obtaining a migration training data set based on the n velocity spectra, and further training the depth learning model based on the migration training data set and the corresponding labels.

It should be noted here that the method of obtaining the migration training data set according to the velocity spectrum is the same as the method of obtaining the training data set based on the velocity spectrum mentioned above, which is not described here.

Preferably, a data deformation processing is further performed when the long-short term memory network is added after the residual network.

Preferably, the data deformation processing is realized by a reshape function in python.

According to the above technical scheme, compared with the prior art, the present disclosure provides the method for automatically picking up seismic velocity based on depth learning, which adopts the residual network and the long-short term memory network to realize seismic velocity pick-up. The residual network can effectively extract the characteristics of the data, and further reduce the training errors between the input value and the actual value. The long-short term memory network can better learn the temporal relationship among the data and enhance the relationship among the data.

In addition, the training data and labels are obtained by the forward modeling method. Compared with the manual calibration method, the forward modeling method can effectively improve the work efficiency and save manpower, and the forward modeling can obtain more fine labels.

In addition, in the technical scheme provided by the disclosure, the difference between modeling data and actual data is eliminated by the migration learning, and the working efficiency is effectively improved.

### BRIEF DESCRIPTION OF THE DRAWINGS

In order to explain the embodiments of the present disclosure or the technical solutions in the prior art more clearly, the following drawings that need to be used in the description of the embodiments or the prior art will be briefly introduced. Obviously, the drawings in the following description are only embodiments of the present disclosure. For those of ordinary skill in the art, other drawings can be obtained based on the drawings disclosed without creative work.

FIG. 1 is the schematic diagram of establishing a horizontal layered velocity model provided by the disclosure.

FIG. 2 is the schematic diagram of converting the velocity model into the CMP gather and velocity spectrum based on forward modeling provided by the disclosure.

FIG. 3 is the schematic diagram of constructing a data set and labels based on the velocity spectrum provided by the present disclosure.

FIG. 4 is the schematic diagram of the deep learning model provided by the present disclosure.

FIG. 5 is the flow chart of eliminating the difference between modeling data and actual data by the migration learning provided by the disclosure.

FIG. 6 is the flow chart of the method for automatically picking up seismic velocity based on depth learning provided by the disclosure.

### DETAILED DESCRIPTION OF THE EMBODIMENTS

Technical solutions of the present disclosure will be clearly and completely described below with reference to the embodiments. Obviously, the described embodiments are only part of the embodiments of the present disclosure, not all of them. Other embodiments made by those skilled in the art without sparing any creative effort should fall within the scope of the disclosure.

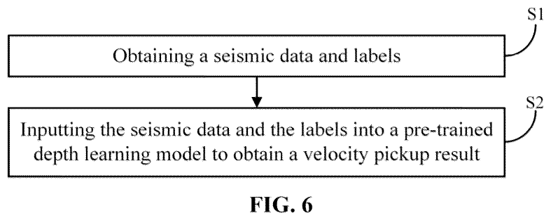

With reference to FIG. 6, an embodiment of the present disclosure provides a method for automatically picking up seismic velocity based on depth learning, including:
Step S1: obtaining a seismic data and labels;
Step S2: inputting the seismic data and the labels into a pre-trained depth learning model to obtain a velocity pick-up result.

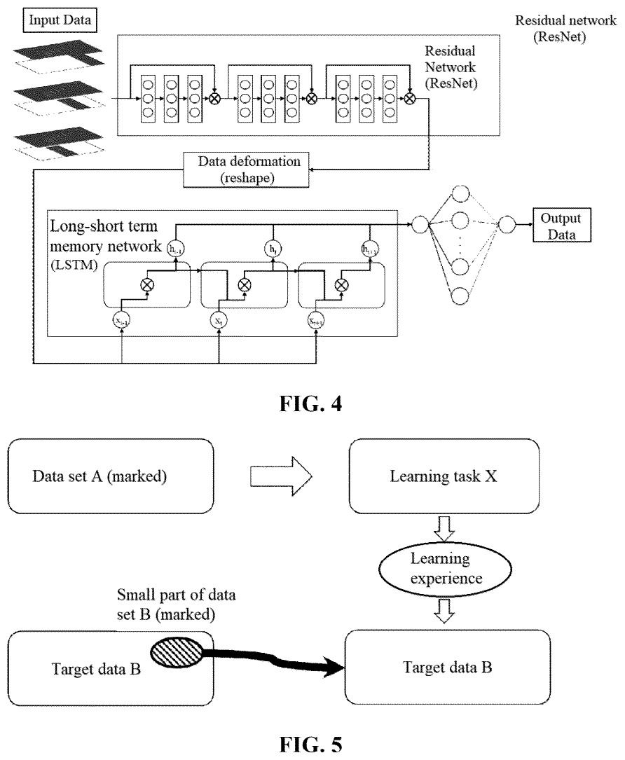

With reference to FIG. 4, a structure of the depth learning model includes a residual network composed of three residual blocks, and after the residual network, a long-short term memory network and a full connection layer are further added.

Each of the residual blocks is composed of three convolutional layers. An activation function between each residual block and each convolutional layer of the residual block is a Relu function. And an activation function between the long-short term memory network and the full connection layer is a Relu function.

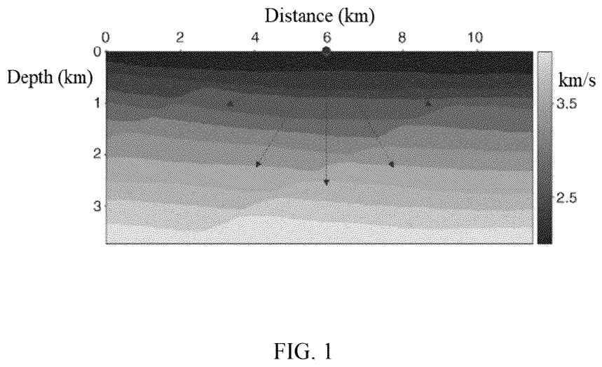

In order to further optimize the above technical solutions, a method for training the depth learning model includes the following steps.
(1) Constructing a training set data and labels, specifically including the following steps.
S21: establishing a horizontal layered velocity model, as shown in FIG. 1. The number of cut-off layers is set to be k, and each layer is an isotropic medium. The velocity of each layer is randomly set, and the range is maintained at the vertical waves 2500 to 4500 m/s. The shock source is arranged on the top layer, the main frequency is the 30 Hz ricker wavelet, and the sampling interval is 0.5 ms (less than the thickness of each layer of medium).
S22: performing a forward modeling on the horizontal layered velocity model based on a wave equation to obtain seismic records. The acoustic equation is expressed as:

$$\{ \begin{matrix}k \frac{{d}^{2} u ( x , t )}{{dt}^{2}} - {∇}^{2} u ( x , t ) = q in Ω \\ u ( x , t = 0 ) = 0 \\ \frac{du ( x , t )}{dt} {\vert}_{t = 0} \\ k = \frac{1}{{c}^{2}}\end{matrix} \qquad ( 1 )$$

where c is an acoustic wave velocity, q denotes a shock source, u(x,t) denotes a function of acoustic wave propagation, k denotes a slow degree, q in Ω denotes a simulated shock source in the model, and Ω denotes a simulated model.

The Dirichlet boundary condition is selected as the boundary condition:

$$u ( x , t ) {\vert}_{δΩ} = 0 \qquad ( 2 )$$

where, δΩ is the surface of the Ω boundary of the model.

The acoustic wave equation is solved by using a finite difference method, and the acoustic wave equation is discretized. Time discretization and spatial discretization are first defined. Based on Taylor expansion, the second-order time derivative is rewritten into discrete form:

$$\frac{{d}^{2} u ( x , t )}{d {t}^{2}} = \frac{u ( x , t + Δ t ) - 2 u ( x , t ) + u ( x , t - Δ t )}{Δ {t}^{2}} + O ( Δ {t}^{2} ) \qquad ( 3 )$$

where u is a discrete wave field, Δt is a discrete time step (distance between two consecutive discrete time points), and O(Δt²) is a discretization error term.

The discrete Laplace operator is defined as the sum of the second-order spatial derivatives in three dimensions:

$$Δ u ( x , y , z , t ) = {\sum }_{j = 1}^{j - \frac{k}{2}} [ {α}_{j} ( u ( x + jdx , y , z , t ) + u ( x - jdx , y , z , t ) + u ( x , y + j d y , z , t ) + u ( x , y - j d y , z t ) + u ( x , y , z + j d z , t ) + u ( x , y , z - j d z , t ) ) ] + 3 {α}_{0} u ( x , y , z , t ) \qquad ( 4 )$$

where, aⱼ and a₀ represent the coefficients generated when summing the second-order spatial derivatives.

After the spatial and temporal discretization are defined, the wave equation is completely discrete in combination with the temporal and spatial discretization, and the following second-order in the temporal discretization and k^{th}-order in the spatial discretization template are obtained to update the position x, y, z of a grid point at time t, that is:

$$u ( x , y , z , t + Δ t ) = 2 u ( x , y , z , t ) - u ( x , y , z , t - Δ t ) + \frac{Δ {t}^{2}}{k ( x , y , z )} ( Δ u ( x , y , z , t ) + q ( x , y , z , t ) ) \qquad ( 5 )$$

Based on the Devito library in python, the discrete Laplace operator and the discrete acoustic equation are defined and solved to obtain the modeling seismic records.
S23: synthesizing a CMP gather based on the seismic records.
S24: calculating a velocity spectrum based on the CMP gather.

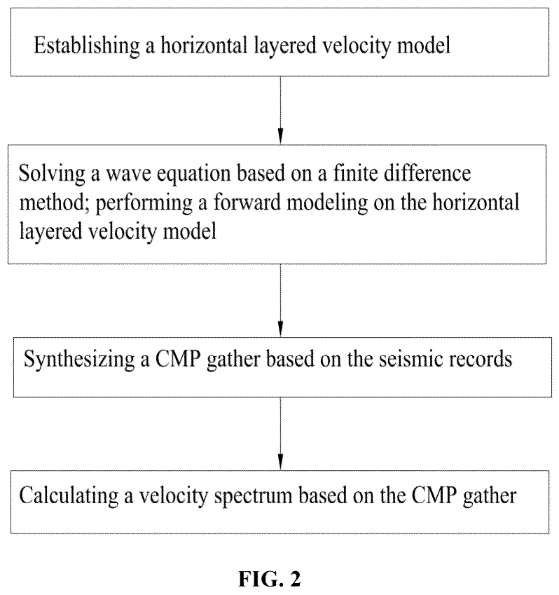

The forward modeling seismic records are seismic records indexed by shot points. In seismic data processing, it is necessary to extract the traces with common central points in the shot set to form a new set, namely CMP gather. The velocity analysis on the CMP gather is carried out, the constant speed scanning correction superimposition on the CMP gather is performed, and the variation of seismic wave along superposition energy with different velocities relative to scanning velocity, that is, the velocity spectrum is obtained (in order to input the velocity spectrum into the depth learning model for training, the velocity spectrum is regarded as a matrix with length a and width b), as shown in FIG. 2.
S25: dividing the velocity spectrum equally into m regions according to a time axis, displaying a region shape of energy information, and setting an energy value of other regions to 0 to obtain a processed velocity spectrum.
S26: superimposing the processed velocity spectrum with the original velocity spectrum to obtain the training set data; and extracting velocity values corresponding to energy maximum points in each region, and configuring the velocity values as the labels.

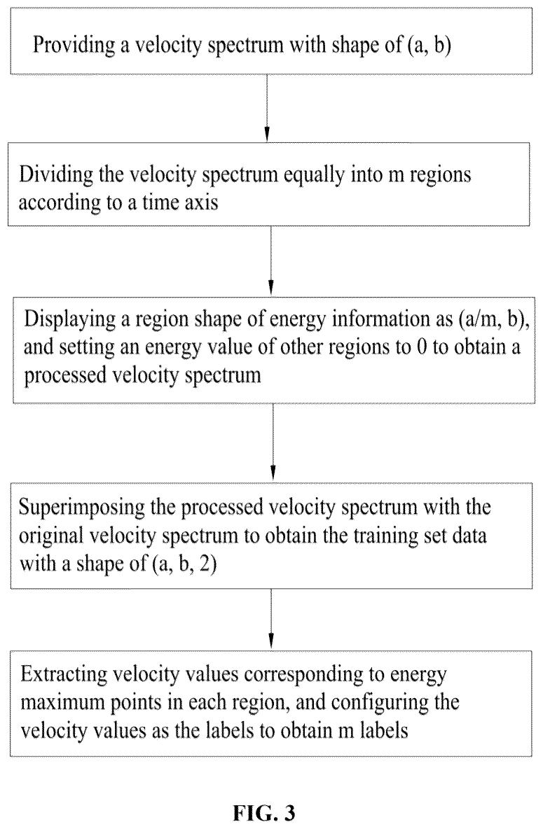

Specifically, since the established velocity model is similar to the horizontal layered model, the root mean square velocity obtained through the velocity spectrum is equivalent to the superposition velocity. The velocity spectrum is processed and divided into m regions equally according to the longitudinal time axis, that is, the length and width of the processed m velocity spectra are still a and b, but the length and width of the regions displaying energy information become a/m and b. The energy values of the other regions are set to 0. The velocity values corresponding to the maximum energy points in each region are extracted and are used as the labels, thus, m labels are obtained. The processed velocity spectra are superimposed with the original velocity spectrum to obtain m training sets with the shape of (a, b, 2) (that is, length a, width b and dimension 2), which is shown in FIG. 3.
(2) Constructing the depth learning model.

The depth learning model includes two algorithms, namely a residual neural network (ResNet) and a long-short term memory network (LSTM). The purpose of the residual network is to extract more features from the velocity spectrum data, and the long-short term memory network is to extract temporal relationships of upper and lower sets of data. When a residual network is established, a residual block structure composed of three convolutional layers is established, and the residual network is composed of the three residual blocks, and an activation function between the residual blocks and each layer of convolutional layers of the residual blocks is set as a Relu function. The long-term memory network has a requirement for the shape of the input data, and the dimension of the input data needs to be three-dimensional, that is, (data feature, data amount, data dimension).

A data deformation processing is further performed when the long-short term memory network is added after the residual network. The data shape after the input data being output through the residual network is 4 dimensions, namely (number of convolution cores, length of convolution cores, width of convolution cores, amount of data after convolution). The shape of the matrix is rearranged by using the reshape function in python. The data shape is changed to (number of data features, amount of data, data dimension of 1) to facilitate training of the long-short term memory network. The number of layers of the long-short term memory network is set to 1 layer, and a full connection layer is added. And an activation function between the long-short term memory network and the full connection layer is set to a Relu function, and reference can be made to FIG. 4 for details.
(3) Inputting the training set data and the labels into the constructed depth learning model for training, and further training the depth learning model by using a migration learning.

The training data and the labels are input into the constructed depth learning model, and the loss function, that is, loss, is set as an MSE (square root) function. The learning rate is set as a dynamic learning rate, and the learning rate is decreased with the increase of the number of training times, so that the loss function can be quickly decreased. The model is trained 1000 times, and the model is output when the loss is lowest.

Since the depth learning model uses modeling data for training, in general, there are errors between the modeling data and the actual data. In order to make the model trained with the modeling data perform well in the actual data, the performance of the depth learning model is improved by the migration learning (the migration learning process is shown in FIG. 4). N velocity spectra are extracted from the actual seismic data (n is much less than the number of velocity spectra contained in the actual seismic data), and labels are obtained by means of manual picking up velocity to obtain a migration training data set and labels, where 70% is used for training the migration learning, and 30% is used for model testing. Since the residual network in the original depth learning network is responsible for learning the features of the data, and the long-short term memory network is responsible for learning the temporal relationship of the data, only the convolution layer of the residual network is updated when migration learning is performed using the actual data, thereby an optimal depth learning model can be obtained. The test data is input into the model and the velocity pick-up result after model processing is obtained.

In summary, the present disclosure provides a method for automatically picking up seismic velocity based on depth learning, and the method has the following innovative points.
(1) In the present disclosure, a residual network (ResNet) and a long-short term memory network (LSTM) are used to realize earthquake speed pick-up, in which the residual network (ResNet) can effectively extract data features, and meanwhile further reduce training errors between the input values and actual values in training. With the long-short term memory network (LSTM), it is possible to better learn the temporal relationship between data and enhance the connection between data.
(2) The training data and the labels in the present disclosure are obtained by using a forward modeling method. Compared with manual calibration method, the forward modeling method can improve work efficiency and save manpower, and the forward modeling can obtain more fine labels.
(3) In the present disclosure, the difference between the modeling data and the actual data is eliminated by using migration learning, and the working efficiency of the present disclosure is effectively improved.

Various embodiments in the present specification are described in a progressive manner, and the emphasizing description of each embodiment is different from the other embodiments. The same and similar parts of various embodiments can be referred to for each other. For the apparatus disclosed in the embodiments, since the apparatus corresponds to the method disclosed in the embodiments, the description is simplified, and reference may be made to the method part for description.

The above description of the disclosed embodiments enables those skilled in the art to realize or use the present disclosure. Many modifications to these embodiments will be apparent to those skilled in the art. The general principle defined herein can be realized in other embodiments without departing from the spirit or scope of the present invention. Therefore, the present disclosure will not be limited to these embodiments shown herein, but will conform to the widest scope consistent with the principle and novel features disclosed herein.

What is claimed is:

1. A method for automatically picking up seismic velocity based on depth learning, comprising:
obtaining a seismic data and labels; and
inputting the seismic data and the labels into a pre-trained depth learning model to obtain a velocity pick-up result;
wherein a structure of the depth learning model comprises a residual network composed of three residual blocks, and after the residual network, a long-short term memory network and a full connection layer are further added;
each of the residual blocks is composed of three convolutional layers; an activation function between each residual block and each convolutional layer of the residual block is a Relu function; and an activation function between the long-short term memory network and the full connection layer is a Relu function.

2. The method of claim 1, wherein a method for training the depth learning model comprises:
constructing a training set data and labels;
constructing the depth learning model; and
inputting the training set data and the labels into the constructed depth learning model for training, and further training the depth learning model by using a migration learning.

3. The method of claim 2, wherein the step of constructing a training set data and labels comprises:
establishing a horizontal layered velocity model;
performing a forward modeling on the horizontal layered velocity model based on a wave equation to obtain seismic records;
synthesizing a CMP gather based on the seismic records;
calculating a velocity spectrum based on the CMP gather;
dividing the velocity spectrum equally into m regions according to a time axis, displaying a region shape of energy information, and setting an energy value of other regions to 0 to obtain a processed velocity spectrum;
superimposing the processed velocity spectrum with the original velocity spectrum to obtain the training set data; and
extracting velocity values corresponding to energy maximum points in each region, and configuring the velocity values as the labels.

4. The method of claim 3, wherein the step of further training the depth learning model by using a migration learning comprises:
extracting n velocity spectra from an actual seismic data, and obtaining labels by manually picking up velocities; and
obtaining a migration training data set based on the n velocity spectra, and further training the depth learning model based on the migration training data set and the corresponding labels.

5. The method of claim 1, wherein a data deformation processing is further performed when the long-short term memory network is added after the residual network.

6. The method of claim 5, wherein the data deformation processing is realized by a reshape function in python.
